(19) United States
(12) Patent Application Publication
(10) Pub. No.: US 2026/0238202 A1
(43) Pub. Date: Aug. 13, 2026

(54) SiGe High-Frequency Pulse-Width Modulation for Low-Noise Applications

(71) Applicant: John Suarez, Newark, DE (US)

(72) Inventor: John Suarez, Newark, DE (US)

(21) Appl. No.: 18/986,640

(22) Filed: Dec. 18, 2024

Related U.S. Application Data
(60) Provisional application No. 63/612,314, filed on Dec. 19, 2023.

(51) Int. Cl. H03K 7/08; H03K 3/26

(52) U.S. Cl. CPC H03K 7/08; H03K 3/26

(57) ABSTRACT

This disclosure details the first-known experimental observation of pulse-width modulation at 100 MHz using silicon-germanium HBT technology. Also provided is an integrated-circuit design with additional flexibility for the end user, with simulated performance results. This result is significant, among other reasons, in that it shows how pulse-width modulation generators can be used in close proximity to sensitive electronics without the need or requirement for shielding of the electrical noise byproduct of such pulse-width modulation generators.

### CROSS-REFERENCE TO RELATED APPLICATION(S)

This patent document claims the benefit of U.S. Provisional Application No. 63/612,314, filed on Dec. 19, 2023. The entire contents of this commonly owned patent application and the references/citations disclosed therein are herewith incorporated by reference.

### STATEMENT REGARDING FEDERALLY-SPONSORED RESEARCH

This invention was made with government support under award number N00014-22-1-2684, awarded by the Office of Naval Research. The government has certain rights in the invention.

### FIELD OF THE INVENTION

Variable-speed motor control, quiet motor control, pulse-width modulation, PWM waveform generation, SiGe circuit design, HBT circuit design.

### BACKGROUND OF THE INVENTION

### I. Introduction

Pulse-width modulation (PWM) is an efficient method for controlling the speed of DC electric motors. A simple circuit for PWM generation and motor control is shown in FIG. 1. The PWM generator provides a square wave whose duty cycle is proportional to the power delivered to the motor. A simulated PWM output is shown in FIGS. 2(a) and 2(b). The off-times of the square wave translate to energy savings, since minimal energy is transferred during those time intervals.

While the efficiency of PWM is an asset, its noise generation is not. As in most engineering designs, the designer must weigh this factor against other design constraints, necessitating trade-offs in the design. This patent document will consider the case in which low-noise performance is a critical design requirement. This would be the case when, for instance, a PWM controller is to be operated in the presence of precision analog electronics, and RF shielding is unavailable and/or ineffective in providing a low-noise environment for the electronics. Examples of such precision analog electronics include those relying on highly-stable frequency references; or low-frequency communication electronics, such as those employing high-sensitivity receivers.

The noise generated by PWM is caused by the square wave employed by PWM. It is well known that a square wave's frequency-domain representation includes harmonic frequencies; these harmonic frequencies are at odd-integer multiples of its fundamental frequency. These harmonic frequencies are interpreted as noise. So, as a consequence, PWM generates noise at frequencies significantly higher than the fundamental operating frequency. And, since PWM employs a square wave whose duty cycle is varied, this adds another time-varying component to that noise.

Most PWM controllers of DC motors operate at frequencies below 1 MHz [1]-[4]. This is primarily for two reasons. Firstly, the time constant of most DC motors is on the order of milliseconds, due to the high inductance present in the coils [5]. In order to effectively control the motor with a time-varying waveform, that waveform must have a period much smaller than the time constant of the motor. So, a PWM frequency on the order of tens of kilohertz is usually sufficient. Secondly, in many industrial applications where DC motors are employed, noise is not a primary concern. But, this disclosure considers the case when low-noise operation is a critical requirement, due to the close proximity of precision analog electronics or communication electronics. Such electronics are generally intolerant of high noise levels. In fact, digital integrated-circuit (IC) designers take special care to separate analog sections from digital sections on the same chip [6]. Embodiments of the present invention provide a solution to the problem of noise generated by PWM—controlled DC motors in proximity to noise-sensitive electronics—without the need for sophisticated shielding.

### SUMMARY OF THE INVENTION

This disclosure details the first-known experimental observation of pulse-width modulation at 100 MHz using silicon-germanium HBT technology. Also provided is an integrated-circuit design with additional flexibility for the end user, with simulated performance results. More generally, embodiments of the invention feature a pulse-width modulation (PWM) generator for supplying electrical energy to an electrical load, the PWM generator featuring pulse-width modulation of the electrical energy; and the PWM generator operating at a fundamental frequency of at least 10 MHz.

### BRIEF DESCRIPTION OF THE DRAWINGS

FIG. 1 shows a simple circuit for PWM generation and motor control.

FIGS. 2(a-b) show a simulated PWM output, e.g., wavefor. FIG. 2(a), simulated PWM waveform for low motor speeds. FIG. 2(b), simulated PWM waveform for high motor speeds.

FIG. 3 shows a schematic diagram of the experimental QPWM setup.

FIGS. 4 (a-e) shows the output waveform of the QPWM system at various duty cycles, taken as screen shots from an oscilloscope. The oscilloscope screen shots, illustrate various pulse widths as the rotary potentiometer is turned clockwise. Notice that the widths of the pulses become wider as the potentiometer is turned.

FIG. 5 shows the schematic of such an IC comparator, with VCC=+3 V and VEE=−3 V. The noninverting input is the base of Q1, the inverting input is the base of Q2, and the output is the emitter of Q5.

FIG. 6(a) is a graph of the simulated performance of the on-chip oscillator in the time-domain space.

FIG. 6(b) is a graph of the simulated performance of the on-chip oscillator in the frequency-domain space.

FIG. 7 shows a single snapshot of the simulated output PWM waveform, generated at 100 MHz.

FIG. 8 shows a picture of the setup in the laboratory; that is a picture of the experimental QPWM setup. Identification of major components: (1) Voltage regulation sub-board, providing ±12 V and ±5 V; (2) Voltage adjustment and voltage-input-limiting sub-board; (3) Voltage-controlled oscillator; (4) ADCMP580 comparator sub-board; (5) PWM waveform output.

### DETAILED DESCRIPTION OF EMBODIMENTS OF THE INVENTION

This disclosure provides the experimental results of PWM generation at 100 MHz, a significantly higher frequency than is commonly used for this purpose. Heterojunction bipolar transistors (HBTs) fabricated in silicon-germanium (SiGe) technology were employed in the system described here. This is a valuable demonstration for three reasons: One, it is the first-known application of PWM using SiGe technology, and so it serves as a useful demonstration of SiGe in a new application space. Two, since PWM has been demonstrated at 100 MHz, this means harmonic components, i.e. noise, can be expected at frequencies above 100 MHz. But, no noise will be expected below 100 MHz. So, by raising the frequency of the PWM to 100 MHz, the PWM is effectively quiet at all frequencies below 100 MHz. But, it is important to note that modern SiGe HBTs have high transition frequencies—and this is the enabler of PWM generation at the higher frequency of 100 MHz. Three, at the time of this writing, SiGe-HBT transition frequencies exceed 250 GHz [7]. So, it is reasonable to assume that PWM can be generated at frequencies significantly higher than 100 MHz using SiGe technology. On the other hand, since PWM to generate electrical energy into an electrical load is known to work at 1 MHz, then seemingly it should also work at frequencies between 1 MHz and 100 MHz, such as, for example, 10 MHz or 50 MHz. Still, a demonstration at 100 MHz serves as a useful point of reference. Also, the PWM waveform at 100 MHz could be reasonably viewed on the oscilloscope in the lab, which had a bandwidth of 350 MHz.

Following Section II, which describes the experimental setup, Section III presents the results obtained with the QPWM system. These results were obtained with a commercially-available SiGe comparator. Although satisfactory results were obtained, it was found that the vertical range of the output-voltage waveform was somewhat awkward. To correct this problem, an IC design is proposed and presented in Section IV. The simulated performance of this IC design is presented in Section V, with concluding discussion provided in Section VI.

### II. Experimental Setup

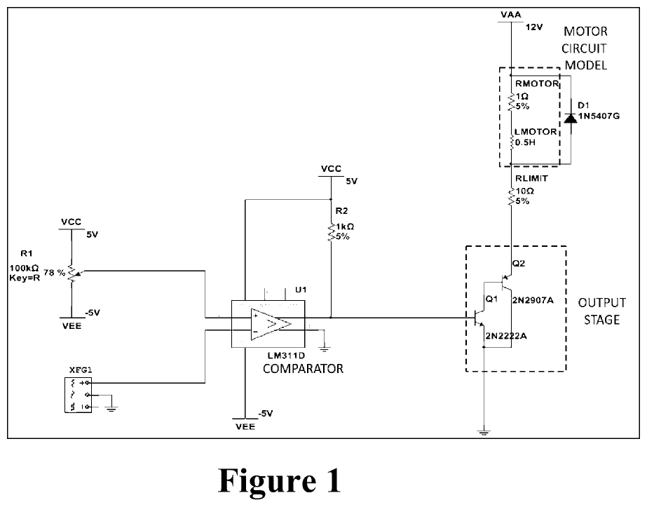

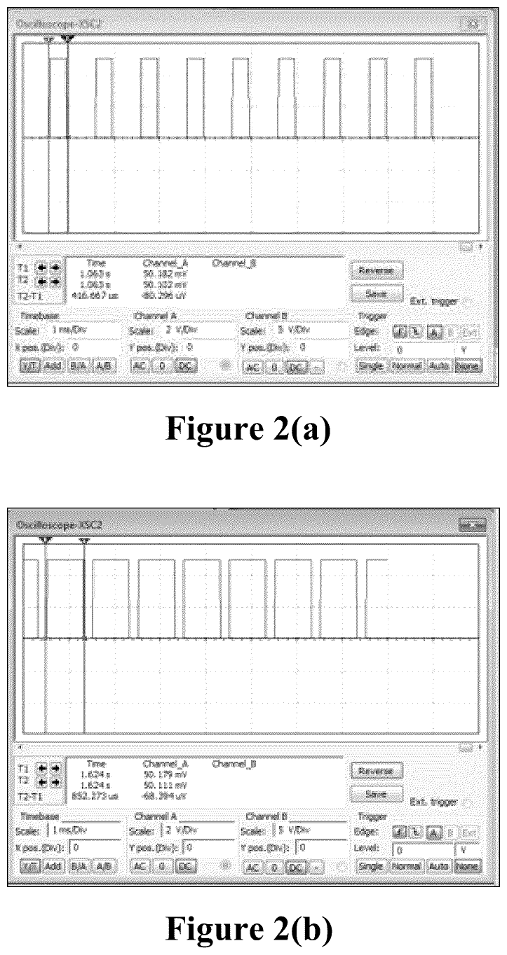

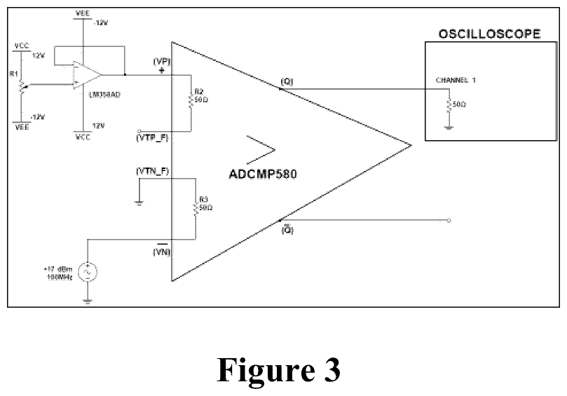

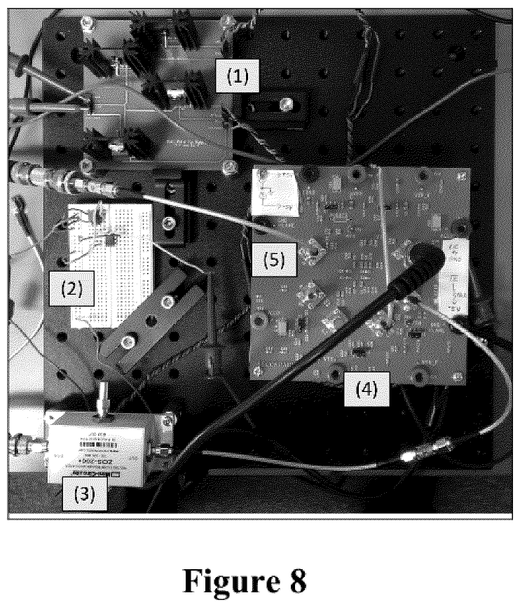

FIG. 3 shows a schematic diagram of the experimental setup, and FIG. 8 shows a picture of the setup in the laboratory. The goal of this system is to demonstrate PWM at 100 MHz, which will be quiet at all frequencies below 100 MHz. This will be referred to as QPWM, with the understanding that the term “quiet” applies at all frequencies below the generation frequency of 100 MHz. While there are noticeable similarities between the QPWM schematic of FIG. 3 and the conventional PWM (CPWM) schematic shown in FIG. 1, important differences should be explained.

As for the first difference between the CPWM and QPWM schematics, notice that the CPWM circuit uses the LM311 IC comparator (Texas Instruments, Inc., Dallas, TX), while the QPWM circuit uses the ADCMP580 IC comparator (Analog Devices, Inc., Wilmington, MA). Now, while the LM311 comparator was fabricated in a standard bipolar process [8], the ADCMP580 comparator was fabricated in a proprietary SiGe process [9]. Also, the ADCMP580 comparator was designed for general use by electronics practitioners, and so various desired options must be set by the user. In the system described here, this was done by making the appropriate connections to the pins of the IC, which are described in the data sheet. The next two paragraphs provide a description of those connections.

As shown in FIG. 3, the inputs of the ADCMP580 are designated VP and VN—the noninverting and inverting inputs, respectively. Those inputs may be separately set as high-resistance inputs or 50-Ω inputs by either grounding or floating the corresponding _F terminal that is in series with the input terminal. For a high-resistance input, the corresponding series terminal, labeled _F, must be left floating. In this case, it was desired to set the VP input as a high-resistance input, and so the corresponding VTP_F terminal was left floating. But, since it was desired to set the VN input as a 50-Ω input, the corresponding VTN_F terminal was grounded. This was done because the input signal generator, which provided the 100-MHz signal, had a 50-Ω output.

FIG. 3 shows a potentiometer connected to an op amp, which is then connected to the noninverting input of the ADCMP580. In the experimental setup, a rotary potentiometer was used; it provided continuous voltage variation from −12 V to +12 V. However, those values are beyond the maximum tolerable values of the ADCMP580. The purpose of the op amp was to limit the input voltages to approximately −10 V to +10 V. This was enabled by the output-voltage saturation provided by LM358 op amps.

As for the second difference between the CPWM and QPWM schematics, notice that the QPWM system required a 100-MHz input sine wave. In the first iteration of the QPWM system, this was provided by a standard RF signal generator with a 50-Ω output; the waveform had a power of +17 dBm. In the second iteration of the system, a standalone voltage-controlled oscillator (VCO) was used. This was a Mini-Circuits ZOS-200+ (MiniCircuits, Brooklyn, NY). It provided +10 dBm output power at 100 MHz.

As for the third difference between the CPWM and QPWM schematics, the CPWM system employed a complementary Darlington output stage for providing high current to a motor. The present iteration of the QPWM system does not include such an output stage. This is because the goal of this system was only to demonstrate the generation of a high-frequency PWM waveform. Future experiments will explore the system's application to DC motors of various sizes and current draws. Such experiments would involve the assembly of different output stages for different classes of motors, depending on their current-draw specifications. So, in this disclosure, the focus is only on the first step: generation of a high-frequency PWM waveform for low-noise applications.

### III. Experimental Results

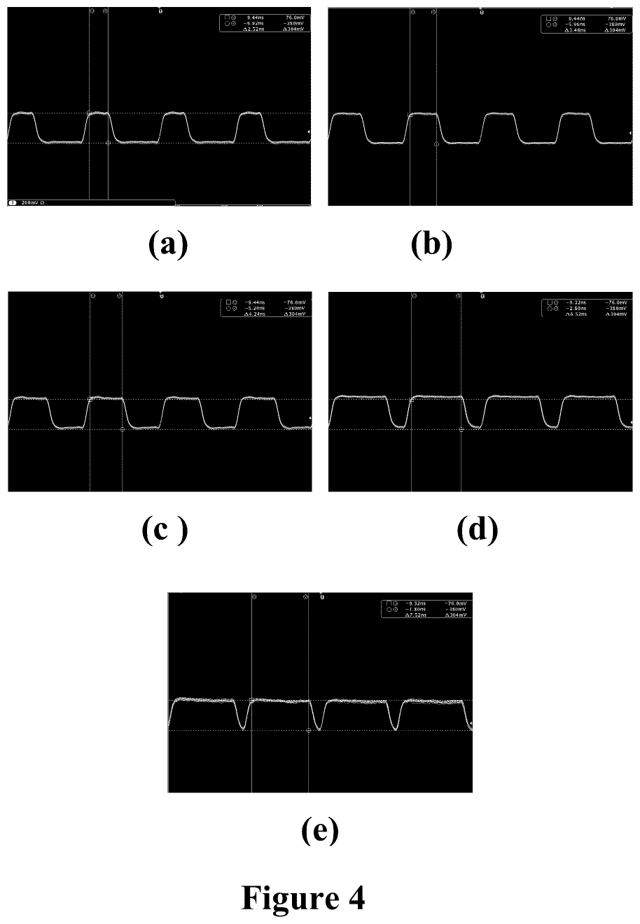

FIG. 4, specifically FIGS. 4(a) through 4(e), shows the output waveform of the QPWM system at various duty cycles, taken as screen shots from an oscilloscope. It is important to show the PWM waveform at various duty cycles because this demonstrates that the system can continuously vary the duty cycle. This means that the system can continuously vary the speed of a motor, should a motor be connected through the appropriate output stage. The duty cycle was varied by turning the rotary potentiometer shown in FIG. 3. The period of the waveform is indicated in each screen shot, as well as the peak-to-peak voltage; i.e. amplitude. Notice that the peak-to-peak voltage is fairly constant, which is an important feature of properly-generated PWM: variable duty cycle, constant amplitude.

One drawback of the QPWM system was the vertical-voltage range of the output PWM waveform. As shown in FIGS. 4(a) through 4(e), this range extended from −380 mV to −76 mV. This is not a desirable voltage range for a PWM waveform; a range from 0 V to some non-zero value is better, preferably a positive value. The reason for the −380-mV to −76-mV range is due to the internal design of the ADCMP580 comparator: it was designed for common-mode logic (CML) digital applications [11], [12]. Within CML applications, the vertical-voltage range shown in FIGS. 4(a-e) is standard. But, for PWM applications—particularly for DC motor control—that range is undesirable.

This is a drawback commonly encountered when using general-purpose components, such as the ADCMP580, outside of their intended application space [9]. The ADCMP580 certainly allows the QPWM system to succeed in providing the desired PWM waveform at the desired frequency. But, the waveform must be upward-vertically shifted in order to be useful for practical motor control. This level shifting adds hardware materials, cost, and complexity to the QPWM system. Instead, it would be desirable if the IC comparator—the heart of the system—provided more practical output-voltage levels, with fine-tuning available if necessary. This will be the subject of the next section.

### IV. Integrated-circuit Comparator Design for QPWM

The ADCMP580 is a commercial IC product manufactured by Analog Devices. Its internal circuit design is proprietary, and it has been fabricated in a SiGe bipolar process that is also proprietary. Therefore, limited details are available beyond those provided in the data sheet.

Since the ADCMP580 was designed for CML applications, it provides an output-voltage range that is impractical for PWM motor control. As discussed in Section III, one way to solve this problem is to perform off-chip level shifting; that is, use a circuit external to the IC chip to adjust the voltage range. Another option is to design a custom IC comparator that is specifically designed for QPWM waveform generation, whose output-voltage range is within acceptable levels. On-chip adjustment of the voltage level could be provided, to compensate for process-variation or post-fabrication factors.

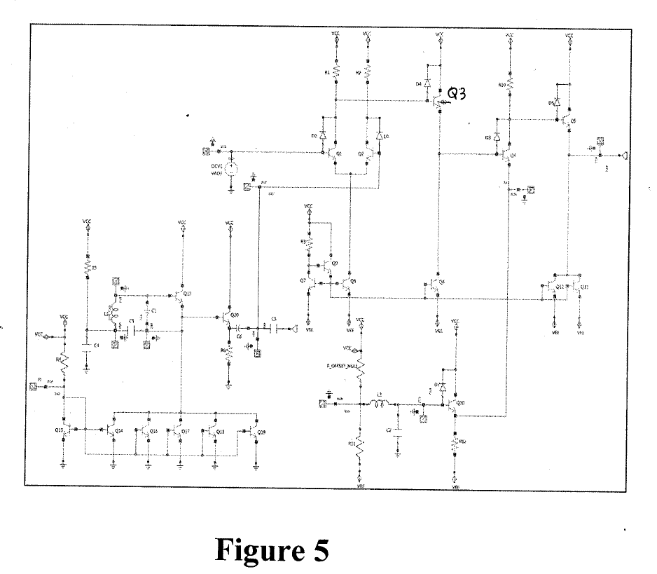

The schematic of such an IC comparator is presented in FIG. 5. The transistors shown in the design are HBTs with a transition frequency of 250 GHz, which comfortably allows for PWM generation at 100 MHz. Transition frequencies greater than 100 GHz are typical of state-of-the-art SiGe HBTs [13].

Some of the transistors shown in the schematic must switch at a high frequency, while others do not. The transistors that are expected to switch rapidly have Schottky-barrier diodes (SBDs) connected between their bases and collectors. This is to prevent those transistors from entering the saturation mode of operation. Bipolar transistors, including HBTs, generally exhibit long switching times when leaving the saturation mode of operation. So, if an HBT is expected to switch rapidly, it is desirable to prevent that HBT from entering saturation. Transistors Q1-Q5 and Q10 are expected to switch rapidly, and so are equipped with SBDs. All the other transistors function as current sinks or current mirrors for DC biasing, and are not required to switch rapidly. Therefore, they are not equipped with SBDs.

The basic operation of the comparator can be understood through the action of transistors Q1-Q5. The comparator's inputs are the bases of Q1 and Q2, serving as the noninverting and inverting inputs, respectively. The comparator's output is the emitter of Q5. Together, transistors Q1 and Q2 comprise the input differential stage. This stage has two branches; one is occupied by Q1 and the other is occupied by Q2. This differential stage has the ability to steer all its current entirely from one side to the other, requiring only a small input-voltage difference between the bases of the transistors—on the order of V_{T}, the thermal voltage. This is how the initial comparison is performed. Q3 is an emitter follower that serves as a voltage buffer. Q4 is a logic inverter that reconditions the voltage logic levels, and Q5 is an emitter follower that provides a low-output-resistance output stage.

Since this comparator was designed specifically for QPWM, it is important that the output voltage waveform ranges from 0 V to a positive value. To ensure this, Q10 provides on-chip adjustment of the vertical-voltage level. Notice the voltage divider comprised of R_OFFSET_NULL and R11. An off-chip potentiometer can be connected here, to allow a user to trim any DC offsets observed in the output. An off-chip RF choke, shown as an inductance connected to the base of Q10, blocks high-frequency signals at that node.

A stable oscillator is required for all PWM generators, and a QPWM generator is no exception. In the experimental setup described in Section II, this was provided by an external signal generator in the first iteration; then by a dedicated local oscillator in the second iteration. In the IC comparator, it is provided on-chip with the assistance of several off-chip components. Q12, C1, R5 (on-chip) and L2, C4 (off-chip) comprise a 100-MHz Colpitts oscillator. Q20 is an emitter follower that provides voltage buffering, so that the base of Q2 does not load the oscillator. Capacitor C5 is needed only so that the oscillator's output waveform can be examined by the simulator.

### V. Simulated QPWM Performance of the IC Comparator

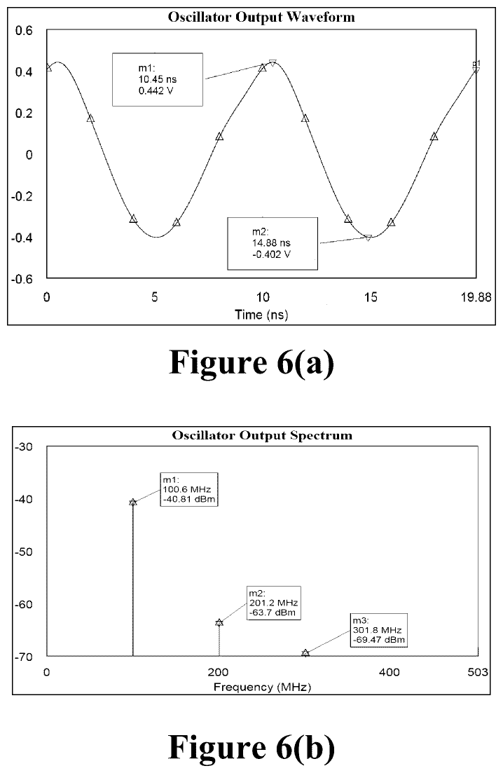

The simulated performance of the on-chip oscillator is shown in FIGS. 6(a) and 6(b), illustrating the time-domain and frequency-domain graphs, respectively. These plots illustrate a fairly clean sine wave output at 100 MHz, with some distortion present. This distortion can be seen in two ways: as an imperfect sine wave in the time domain, or with harmonic distortion in the frequency domain. Of course, the term “fairly clean” is somewhat subjective. What is meant is a best compromise among the competing goals of minimum on-chip real estate, minimum harmonic distortion, minimum voltage offset, minimum oscillator startup time, and maximum output-voltage amplitude. The waveform shown in FIG. 6(a) is the best compromise among these competing goals. The use of the simulator allowed for optimization of these parameters while carefully inspecting the output PWM waveform for acceptable performance. That performance will be described now.

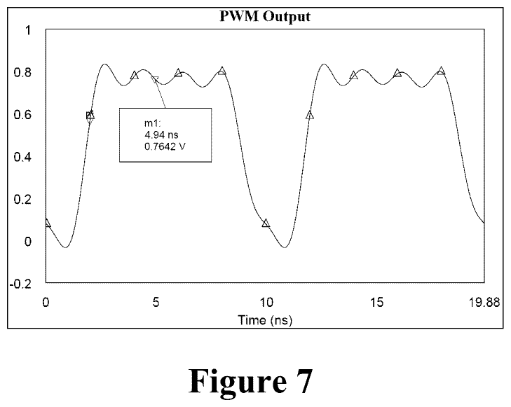

The output PWM waveform was taken at the emitter of Q5. The duty cycle of the output PWM waveform was varied by connecting a variable DC voltage source to the noninverting input, that is, the base of Q1. Similar to the screen shots provided in FIGS. 4(a)-(e), the duty cycle was continuously varied by changing the value of the variable source. FIG. 7 shows a single snapshot of the output PWM waveform. To save space, only one snapshot is provided. This is because the duty-cycle variation was continuous with respect to the voltage adjustment, similar to what was shown in FIGS. 4(a)-(e).

Three important differences between the FIGS. 4(a)-(e) and FIG. 7 waveforms should be emphasized. Firstly, notice that PWM waveform in FIG. 7 starts at approximately 0V, and extends upward to a positive value. This shows correction of the awkward vertical-voltage levels due to the ADCMP580. This was an important design goal, and was enabled by transistor Q10, shown in FIG. 5. The value of R_OFFSET_NULL, connected to the base of Q10, was adjusted until the bottom of the PWM waveform coincided with 0 V. Secondly, a closer look will reveal that the waveform in FIG. 7 extended between approximately 0 V and 0.8 V, giving a dynamic range of approximately 0.8 V. This is considerably larger than the dynamic range of the FIGS. 4(a)-(e) waveforms, which was approximately 0.304 V. This implies that the task of interfacing the IC comparator to an output stage may be easier, if such an output stage requires a forward-bias voltage of 0.6 V. Thirdly, notice the voltage ripple present in the FIG. 7 waveform. This is a disadvantage, although not a severe one. It is not considered a severe disadvantage because the ripple is small, and is of higher frequency—greater than the operational frequency of 100 MHz. This ripple is not expected to significantly affect the PWM performance, although this would need to be confirmed by additional experiments.

### VI. Conclusions, Industrial Applicability, and Planned Future Work

This disclosure has provided the first-known published demonstration of PWM generation at 100 MHz in SiGe technology, for noise-sensitive applications requiring quiet performance below 100 MHz. Section II described the experimental setup and Section III provided the experimental results, while calling attention to an important deficiency—that is, the awkward voltage levels of the output waveform. The reason for those levels was due to the ADCMP580 comparator, an off-the-shelf, commercial IC designed for general use. While those voltage levels could have been corrected by external level shifting, it was found that a custom IC-comparator design would provide more appropriate voltage levels at the outset. That design was presented in Section IV, and its simulated performance was presented in Section V. This was also seen as an opportunity to make the QPWM system more compact, with the 100-MHz local oscillator included on the same chip as the comparator.

While this disclosure has focused on PWM generation at 100 MHz, it is important to understand the extendibility of the results presented here. The transistors used in both the ADCMP580 comparator and custom IC comparator were SiGe HBTs with high transition frequencies. So, it is reasonable to assume that if PWM can be performed at 100 MHz with these devices, it can also be performed at frequencies greater than 100 MHz, as well as at frequencies less than 100 MHz, for example, at 50 MHz or 10 MHz. Still, the 100-MHz demonstration serves as a useful starting point. It is a significantly higher frequency than all other known demonstrations of PWM, while it was built with reasonably priced components. This is an important consideration since the cost of radio-frequency hardware, and the complexity of radio-frequency designs, generally increases with operating frequency. Now, it is easier to justify the greater expense and complexity of higher-frequency work, since confidence has been gained through the 100-MHz demonstration.

What is the significance of the results presented here? Why perform PWM at elevated frequencies at all? The answers to these questions were explained in Section I, but are summarized here: if we perform PWM at 100 MHz, we are making the PWM quiet at all frequencies below 100 MHz. The use of SiGe HBTs, as demonstrated in this disclosure, further shows that PWM can be performed at higher frequencies than 100 MHz; for instance, 5 GHz. In that case, the PWM would be quiet at all frequencies below 5 GHz. This would allow the PWM generator to be in close proximity with communications electronics operating in most of the common commercial bands [10]. In other words, the PWM generator no longer has to be spatially distant from the communications electronics, or no longer needs electromagnetic shielding to prevent the communications electronics from “seeing” the harmonic “noise”.

The work presented in this disclosure will be continued through these four efforts: (1) the pairing of the PWM waveform with various output stages, to demonstrate practical variable control of DC motors; (2) experimental analysis of the harmonic generation from the higher-frequency PWM, expected to be minimal at frequencies below the generation frequency; (3) refinement of the IC comparator design, fabrication of the IC, and experimental testing of the fabricated IC; (4) extension of the 100-MHz results to higher frequencies.

Although the invention has been described in terms of particular embodiments and applications, one of ordinary skill in the art, in light of this teaching, can generate additional embodiments and modifications without departing from the spirit of or exceeding the scope of the principles of the invention.

Accordingly, it is to be understood that the drawings and descriptions herein are proffered by way of example to facilitate comprehension of the invention and should not be construed to limit the scope thereof. Persons skilled in the art will appreciate that the described embodiments are presented for purposes of illustration rather than of limitation. Although the invention has been described in terms of particular embodiments and applications, one of ordinary skill in the art, in light of this teaching, can generate additional embodiments and modifications without departing from the spirit of or exceeding the scope of the principles of the invention.

### REFERENCES

[1] DRV8256E H-Bridge Motor Driver with Integrated Current Sense and Smart Tune Technology: Data Sheet, Texas Instruments, 2021.
[2] TB9120AFTG Bipolar Stepping Motor Driver with a Clock Input Interface for Automotive Applications: Data Sheet, Toshiba 2020.
[3] BD6124EFV Multifunction Single-Phase Full-Wave Fan Motor Driver: Data Sheet, Rohm Semiconductor, 2017.
[4] NFAQ1560R43T Intelligent Power Module: Data Sheet, On Semiconductor, 2021.
[5] W. Wu, “DC Motor Identification Using Speed Step Responses,” Proceedings of the American Control Conference, 2010.
[6] Q. Ma, L. Xiao, Y. Tam, and E. Young, “Simultaneous Handling of Symmetry, Common Centroid, and General Placement Constraints,” IEEE Transactions on Computer-Aided Design of Integrated Circuits and Systems, Vol. 30, No. 1, 2011.
[7] H. Rücker and B. Heinemann, “High-Performance SiGe HBTs for Next-Generation BiCMOS Technology,” Semiconductor Science and Technology, Issue 33, No. 114003, 2018.
[8] LM311 Differential Comparator: Data Sheet, Texas Instruments, 2017.
[9] ADCMP580 Ultrafast SiGe Voltage Comparator: Data Sheet, Analog Devices, 2016.
[10] M. Karim and A. Hossain, “SAR Analysis of Human Head Model Using Common Antennas of 4G LTE Mobile Communications,” Proceedings of the Fourth International Conference on Electrical, Computer and Communication Technologies (ICECCT), 2021.
[11] D. Sreya, A. Kumar, and P. Kalyani, “Dynamic Comparator Design for High Speed ADCs,” Proceedings of the First International Conference on Electrical, Electronics, Information and Communication Technologies (ICEEICT), 2022.
[12] D. Donadkar and S. Bhandari, “Review on Comparator Design for High Speed ADCs,” Proceedings of the International Conference on Computing Communication Control and Automation, 2015.
[13] S. Maas and D. Tait, “Parameter-extraction method for heterojunction bipolar transistors,” IEEE Microwave and Guided Wave Letters, vol. 2, no. 12, 1992.

What is claimed is:

1. A pulse-width modulation (PWM) generator configured to function in close physical proximity to electronics that are sensitive to electrical noise, said PWM generator comprising:
(a) a PWM generator configured to operate at a fundamental frequency whose harmonics are too high to interfere with said electronics; and
(b) an absence of a requirement for electrical shielding between said generator and said electronics.

2. The PWM generator of claim 1, comprising SiGe transistors.

3. The PWM generator of claim 2, wherein said SiGe transistors comprise heterojunction bipolar transistors.

4. The PWM generator of claim 1, wherein said electronics comprise precision analog electronics.

5. The PWM generator of claim 4, wherein said precision analog electronics comprise at least one of (i) electronics that are highly reliant on highly stable frequency references, and (ii) low frequency communications.

6. The PWM generator of claim 1, used to power a DC electric motor.

7. The PWM generator of claim 1, wherein said fundamental frequency is at least 10 MHz.

8. The PWM generator of claim 1, wherein said fundamental frequency is at least 100 MHz.

9. The PWM generator of claim 1, wherein said fundamental frequency is no more than 250 GHz.

10. A pulse-width modulation (PWM) generator for supplying electrical energy to an electrical load, comprising:
pulse-width modulation of the electrical energy; and
said PWM generator operating at a fundamental frequency of at least 10 MHz.

11. The PWM generator of claim 10, further comprising said electrical load featuring a DC electric motor.

12. The PWM generator of claim 10, wherein a voltage of said electrical energy has an amplitude between zero and a positive value.

13. The PWM generator of claim 10, wherein said electrical energy is of a single polarity only.

14. The PWM generator of claim 10, comprising heterojunction bipolar transistors.

15. The PWM generator of claim 14, comprising SiGe transistors.

16. The PWM generator of claim 10, wherein said fundamental frequency is no greater than 250 GHz.

17. The PWM generator of claim 16, wherein said fundamental frequency lies in a range between 100 MHz and 5 GHz.

18. The PWM generator of claim 10, positioned in close proximity to precision analog electronics without a requirement for shielding the electronics from electrical noise generated by said PWM generator.

19. A pulse-width modulation (PWM) generator for supplying electrical energy to an electrical load, comprising:
pulse-width modulation of the electrical energy; and
SiGe transistors configured to operate in a switching role.

20. The PWM generator of claim 19, wherein said SiGe transistors are capable of switching rapidly at a frequency of at least 10 MHz without entering a saturation condition.
